(19) United States
(12) Patent Application Publication
(10) Pub. No.: US 2020/0036303 A1
(43) Pub. Date: Jan. 30, 2020

(54) Thermal electricity conversion based on the heat extracted from underground coal fires

(71) Applicant: China university of mining and technology, Xuzhou, Jiangsu, OT (CN)

(72) Inventors: Fubao Zhou, Xuzhou, Jiangsu (CN); Hetao Su, Xuzhou, Jiangsu (CN); Bobo Shi, Xuzhou, Jiangsu (CN); Haining Qi, Xuzhou, Jiangsu (CN); Jinshi Li, Xuzhou, Jiangsu (CN)

(21) Appl. No.: 15/735,598

(22) PCT Filed: Dec. 14, 2016
(86) PCT No.: PCT/CN2016/109811

§ 371 Date: Dec. 11, 2017

(30) Foreign Application Priority Data
Oct. 17, 2016 (CN) 201610901215.X

(51) Int. Cl. H02N 11/00; H01L 35/30; H02J 7/32

(52) U.S. Cl. CPC H02N 11/002; H02J 7/32; H01L 35/30

(57) ABSTRACT

Thermal electricity conversion based on the heat extracted from underground coal fires, comprising a coalfield fire area (1), coalfield drill holes (2), underground heat conduction pipelines (3) and a heat conduction container (4) which is provided with a pressure relief device (5) thereon and further comprises thermoelectric power generation chip sets (6) and a storage battery (7), wherein the thermoelectric power generation chip sets (6), having cold-side radiator pipes (8) provided on outer sides thereof, are provided on an outer side wall of the heat conduction container (4). The thermoelectric power generation chip sets in the invention are directly attached on the heat conduction container, so that the system is simple in structure without redundant components and high in heat conduction efficiency. The thermoelectric power generation chip sets, having the cold side radiator pipes on outermost layers thereof, are surface mounted so that the contact area among heating media, refrigerants and the thermoelectric power generation chip sets, and the thermal energy of the subsurface fire may be utilized efficiently. The thermoelectric power generation system is simple in process and may be well adapted to the engineering operating environment in the coalfield fire area.

### FIELD OF INVENTION

The present belongs to the technical field of heat recovery in coalfield fire area, and more particularly relates to thermal electricity conversion based on the heat extracted from underground coal fires.

### BACKGROUND OF THE INVENTION

Subsurface fire (SF) is a general term for coalfield fire and coal mine fire formed by the coal seam resulted from human factors or spontaneous combustion, and is commonly occurred in China, the United States, Australia, India, Indonesia and other countries, resulting in: \textcircled{1} loss of a large number of coal resources (the global loss is about 1 billion tons/year while the current coal consumption in the whole world is 8 billion tons/year); \textcircled{2} threatening the mining safety (the raw coal mining process and the mining safety are seriously affected by the subsidence areas and the burned out areas resulted from combustion of the subsurface fire, resulting in blockage of resources or even mining accidents); \textcircled{3} waste of a lot of energy (the energy generated by combustion of the subsurface fire is about 1000 GW/year which is 400 GW/year more than the total global nuclear power capacity); and \textcircled{4} destroying the ecological environment (the annual CO2 emission generated by the subsurface fire accounts for 10% of that in the whole world. The coal fire seriously threatens human health, resulting in a series of related diseases such as respiratory disease, skin cancer and heart disease; the harmful chemicals, such as mercury, selenium and other heavy metals, sulfides and PM2.5, which are released into the air and accumulated in a long term, will pollute air, land and water).

The impact of the coalfield field fire on the environment cannot be ignored, resulting in serious \textcircled{1} air pollution, where lots of heat, toxic and harmful gases and greenhouse gases are emitted into the atmosphere; \textcircled{2} water pollution, where acid-base compounds generated by combustion of the coal fire area are discharged in spring and mine water form from the earth surface along bedrock fissure water at valley mouths, cliffs and steeps, or constantly moved along the groundwater; \textcircled{3} destruction of ground vegetation, where the surface temperature of the coalfield fire area rises sharply to destroy the original physical structure and nature of the soil, while the sulfate and sulfur precipitated in the coalfield fire area increase the soil acidity, so that the sulfur content is increased and the vegetation cannot survive; and \textcircled{4} potential geological hazards, where the burned out area is formed after combustion of shallow coal seams, underground float coal, coal pillars and the like, thus changing the balanced state between the coal seam roof and the surrounding rocks, resulting in a large number of combustion fractures, collapse pits and the like on the ground while providing oxygen supply channels for combustion of the coal seams, and forming a vicious cycle of “combustion-collapse-combustion”; moreover, the soil and water retention capacity of the earth surface is dropped significantly, thereby easily leading to debris flow, landslides and other geological disasters.

On the one hand, although China has made great progress in the field of coal fire research and obtained a number of original achievements, there is still considerable room for improvement in comparison with the developed countries such as Australia and the United States in terms of basic theory research of coal fire and coal fire control. On the other hand, along with the dynamic development of the coalfield fire area, the scale and scope of the coalfield fire area in some areas are still expanding, and the burning area and scale are still increasing. However, the existing fire prevention theory, technology and equipment cannot fully adapt to the development of the subsurface fire. In summary, there is an urgent need for the state to strengthen the continuous investment and layout in coal fire control to achieve the effective control of coal fire and the effective utilization of thermal energy resources. The existing coal fire control techniques, which generally extinguish the fire by grouting or injecting liquid nitrogen to prevent the spreading of coal fire but cannot block the energy accumulation of the subsurface fire, are mostly palliatives without good effect. According to the invention, the system can extract the thermal energy of subsurface fire for power generation, which not only blocks the spreading of coal fire, but also utilizes the accumulated energy of the subsurface fire and completely blocks the conditions for formation of coal fire. Moreover, it has obvious economic and environmental benefits and great significance.

### SUMMARY OF THE INVENTION

In view of the problems that the coalfield subsurface fire wastes coal resources, pollutes the environment and the like, an object of the invention is to provide a thermal electricity conversion based on the heat extracted from underground coal fires, in order to realize the recovery of thermal energy resources of coalfield subsurface fire and to solve the problem of environmental pollution in the coalfield fire area.

To solve the above technical problems, technical solutions provided in the invention are as follows: thermal electricity conversion based on the heat extracted from underground coal fires is provided, comprising a coalfield fire area, and coalfield drill holes provided on the coalfield fire area; underground heat conduction pipelines with enclosed bottoms are provided in the coalfield drill holes, one end of each of the underground heat conduction pipelines is located in the underground for absorbing heat and the other end thereof is provided with a heat conduction container communicated thereto; the heat conduction container is provided with a pressure relief device thereon and further comprises thermoelectric power generation chip sets for generating electricity and a storage battery connected to the thermoelectric power generation chip sets for storing electricity; the thermoelectric power generation chip sets, having cold side radiator pipes provided on outer sides thereof, are provided on an outer side wall of the heat conduction container and located between the heat conduction container and the cold side radiator pipes, and a radiator and a pump are connected to and provided on the cold side radiator pipes.

In comparison with the prior art, the invention has the following beneficial effects: the thermoelectric power generation chip sets in the invention are directly attached on the heat conduction container, so that the system is simple in structure without redundant components and high in heat conduction efficiency. The thermoelectric power generation chip sets, having the cold side radiator pipes on outermost layers thereof, are surface mounted, so that the contact area among heating media, refrigerants and the thermoelectric power generation chip sets is increased, and the thermal energy of the subsurface fire may be utilized efficiently. The thermoelectric power generation system is simple in process and may be well adapted to the engineering operating environment in the coalfield fire area.

The underground heat conduction pipelines are mounted by 5 coalfield drill holes deeply located in the coalfield fire area, so that the more thermal energy of the coal fire may be extracted, the extraction efficiency of the thermal energy of the coal fire is improved and the generating capacity is enhanced. The high efficiency heat conduction container is used for storing the heating media, and the thermoelectric power generation chip sets, having the cold side radiator pipes on the outermost layers thereof, are surface mounted, so that the contact area among heating media, refrigerants and the thermoelectric power generation chip sets is increased, and the thermal energy of the subsurface fire may be utilized efficiently. The thermoelectric power generation system is simple in process and may be well adapted to the engineering operating environment in the coalfield fire area. The cooling water radiator designed with multi-loop bending cooling fins is adopted, so that the cooling area of the cold water may be increased to accelerate heat dissipation and improve power generation efficiency.

As an improvement, there are at least two underground heat conduction pipelines both connected to the heat conduction container. There are 5 coalfield drill holes and 5 underground heat conduction pipelines, and the underground heat conduction pipelines comprise one main heat conduction pipeline located in the middle and four auxiliary heat conduction pipelines uniformly distributed around. The underground heat conduction pipelines may be mounted by 5 coalfield drill holes deeply located in the coalfield fire area, so that the more thermal energy of the coal fire may be extracted, the extraction efficiency of the thermal energy of the coal fire is improved and the generating capacity is enhanced.

As an improvement, the main heat conduction pipeline is a long pipeline and may be used for grouting, extinguishing and sealing the subsurface fire after the thermal energy utilization, and the auxiliary heat conduction pipelines 3.2 are short pipelines only used for sealing the subsurface fire after the thermal energy utilization. The 5 heat conduction pipelines increase the flow rate of the heating media, accelerate the utilization rate of underground thermal energy and improve the power generation efficiency.

As an improvement, the pressure relief device is an automatic pressure relief device comprising a pressure sensor for measuring the pressure in the heat conduction container and an automatic pressure relief valve which relives the pressure automatically when the pressure in the container is excessive.

As an improvement, a hot side module consists of the heat conduction container, the underground heat conduction pipelines and the thermoelectric power generation chip sets, and a cold side module consists of the cold-side radiator pipes, the thermoelectric power generation chip sets, the radiator and the pump. The contact area among the heating media, the refrigerants and the thermoelectric power generation chip sets of such thermoelectric power generation module is large, so that the heat conduction speed of the hot side is fast, the cold side is cooled obviously and the extraction efficiency of the thermal energy of the coal fire is high.

As an improvement, the side wall of the heat conduction container is of a concave or convex structure, and the heat conduction container is of a cruciform structure as a whole. Such structure increases the contact area between the thermoelectric power generation chip sets and the heat conduction container, and the extraction efficiency of the thermal energy of the coal fire is high.

As an improvement, the pump is a pump capable of adjusting flow rate, and may adjust the flow rate of the refrigerants according to the temperature of the heat conduction container in the concrete operation so as to improve the power generation efficiency of the thermoelectric power generation module.

As an improvement, pipelines in the cooling water radiator have a multi-loop bending design, so that the cooling area of the cold water may be increased to accelerate heat dissipation and improve power generation efficiency.

As an improvement, the thermoelectric power generation chip sets are covered on a surface of the heat conduction container and formed by connecting in series and in parallel.

### BRIEF DESCRIPTION OF THE DRAWINGS

FIG. 1 is a structural diagram of a thermal electricity conversion based on the heat extracted from underground coal fires of the invention.

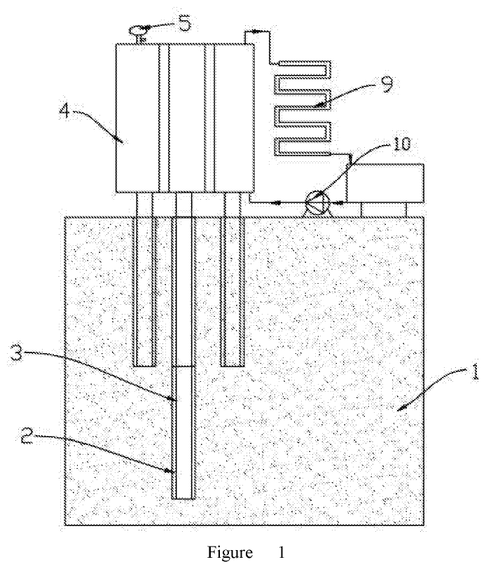

FIG. 2 is a top view of the thermal electricity conversion based on the heat extracted from underground coal fires of the invention.

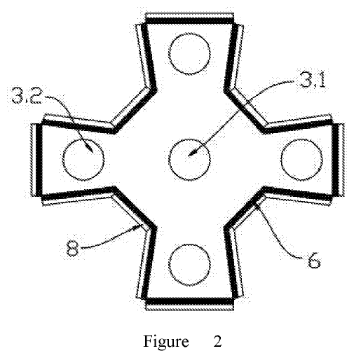

FIG. 3 is a structural diagram of a thermoelectric power generation chip set of the thermal electricity conversion based on the heat extracted from underground coal fires of the invention.

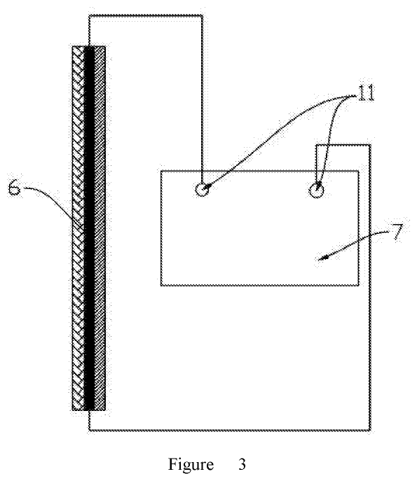

In which: 1, coalfield fire area; 2, coalfield drill hole; 3, underground heat conduction pipeline; 3.1, main heat conduction pipeline; 3.2, auxiliary heat conduction pipeline; 4, heat conduction container; 5, pressure relief device; 6, thermoelectric power generation chip set; 7, storage battery; 8, cold side radiator pipe; 9, radiator; 10, pump; and 11, storage battery terminal.

### DETAILED DESCRIPTION OF SOME EMBODIMENTS

The invention will be further described in detail as follows with reference to the drawings.

With reference to the drawings, a thermal electricity conversion based on the heat extracted from underground coal fires is provided, comprising a coalfield fire area 1, and coalfield drill holes 2 provided on the coalfield fire area 1. Underground heat conduction pipelines 3 with enclosed bottoms are provided in the coalfield drill holes 2, one end of each of the underground heat conduction pipelines 3 is located in the underground for absorbing heat and the other end thereof is provided with a heat conduction container 4 communicated thereto; the heat conduction container 4 is provided with a pressure relief device 5 thereon and further comprises thermoelectric power generation chip sets 6 for generating electricity and a storage battery 7 connected to the thermoelectric power generation chip sets 6 for storing electricity; the thermoelectric power generation chip sets 6, having cold side radiator pipes 8 provided on outer sides thereof, are provided on an outer side wall of the heat conduction container 4 and located between the heat conduction container 4 and the cold side radiator pipes 8, and a radiator 9 and a pump 10 are connected to and provided on the cold side radiator pipes 8.

There are at least two underground heat conduction pipelines 3 both connected to the heat conduction container 4.

There are 5 coalfield drill holes 2 and 5 underground heat conduction pipelines 3, and the underground heat conduction pipelines 3 comprise one main heat conduction pipeline 3.1 located in the middle and four auxiliary heat conduction pipelines 3.2 uniformly distributed around.

The main heat conduction pipeline 3.1 is a long pipeline and the auxiliary heat conduction pipelines 3.2 are short pipelines.

The pressure relief device 5 is an automatic pressure relief device comprising a pressure sensor for measuring the pressure in the heat conduction container 4 and an automatic pressure relief valve.

A hot side module consists of the heat conduction container 4, the underground heat conduction pipelines 3 and the thermoelectric power generation chip sets 6, and a cold side module consists of the cold side radiator pipes 8, the thermoelectric power generation chip sets 6, the radiator 9 and the pump 10.

The side wall of the heat conduction container 4 is of a concave or convex structure, and the heat conduction container 4 is of a cruciform structure as a whole.

The pump 10 is a pump capable of adjusting flow rate.

Pipelines in the cooling water radiator 9 have a multi-loop bending design.

The thermoelectric power generation chip sets 6 are covered on a surface of the heat conduction container 4 and formed by connecting in series and in parallel.

In the specific embodiment, the underground heat conduction pipelines are mounted by 5 coalfield drill holes deeply located in the coalfield, the high efficiency heat conduction container in which heating media are injected is communicated with and provided on upper portions of the underground heat conduction pipelines, so that the heating media absorb heat of the subsurface fire through the underground heat conduction pipelines deeply located in the underground and bring the heat to the high efficiency heat conduction container, thereby heating up the heating media in the container. The hot side of the thermoelectric power generation chip set is supplied with heat by the heating media in the high efficiency heat conduction container, and the cold side thereof radiates heat by the cold side module consisting of the cooling water radiator, the water pump, the cold side radiator pipes and the thermoelectric power generation chip sets. The electric energy output by the thermoelectric power generation chip sets is stored in the storage battery.

A plurality of the devices in the invention may be provided on the coalfield fire area for recovering heat. The system is simple and practical in structure and suitable for engineering operating environment, may generate electricity by using thermal energy of subsurface fire in the coalfield fire area to avoid the spreading of coal fire and the loss of coal resources, and has obvious economic and environmental benefits and great significance.

The descriptions for the invention and the embodiments thereof have no limitation; the embodiment shown in the drawings is only one of the embodiments of the invention, and the actual structure is not limited thereto. All in all, the structure modes and the embodiments similar to the technical solution which are designed by persons of ordinary skill in the art enlightened by above without creative efforts shall fall within the protection scope of the invention.

1. Thermal electricity conversion based on the heat extracted from underground coal fires, comprising a coalfield fire area (1), and coalfield drill holes (2) provided on the coalfield fire area 1; underground heat conduction pipelines (3) with enclosed bottoms are provided in the coalfield drill holes (2), one end of each of the underground heat conduction pipelines (3) is located in the underground for absorbing heat and the other end thereof is provided with a heat conduction container (4) communicated thereto; the heat conduction container (4) is provided with a pressure relief device (5) thereon and further comprises thermoelectric power generation chip sets (6) for generating electricity and a storage battery (7) connected to the thermoelectric power generation chip sets (6) for storing electricity; the thermoelectric power generation chip sets (6), having cold-side radiator pipes (8) provided on outer sides thereof, are provided on an outer side wall of the heat conduction container (4) and located between the heat conduction container (4) and the cold-side radiator pipes (8), and a radiator 9 and a pump (10) are connected to and provided on the cold-side radiator pipes (8).

2. Thermal electricity conversion based on the heat extracted from underground coal fires according to claim 1, wherein there are at least two underground heat conduction pipelines (3) both connected to the heat conduction container (4).

3. Thermal electricity conversion based on the heat extracted from underground coal fires according to claim 1, wherein there are 5 coalfield drill holes (2) and 5 underground heat conduction pipelines (3), and the underground heat conduction pipelines (3) comprise one main heat conduction pipeline (3.1) located in the middle and four auxiliary heat conduction pipelines (3.2) uniformly distributed around.

4. Thermal electricity conversion based on the heat extracted from underground coal fires according to claim 3, wherein the main heat conduction pipeline (3.1) is a long pipeline and the auxiliary heat conduction pipelines (3.2) are short pipelines.

5. Thermal electricity conversion based on the heat extracted from underground coal fires according to claim 1, wherein the pressure relief device (5) is an automatic pressure relief device comprising a pressure sensor for measuring the pressure in the heat conduction container (4) and an automatic pressure relief valve.

6. Thermal electricity conversion based on the heat extracted from underground coal fires according to claim 1, wherein a hot side module consists of the heat conduction container (4), the underground heat conduction pipelines (3) and the thermoelectric power generation chip sets (6), and a cold side module consists of the cold-side radiator pipes (8), the thermoelectric power generation chip sets (6), the radiator (9) and the pump (10).

7. Thermal electricity conversion based on the heat extracted from underground coal fires according to any one of claims 1 to 6, wherein the side wall of the heat conduction container (4) is of a concave or convex structure, and the heat conduction container (4) is of a cruciform structure as a whole.

8. Thermal electricity conversion based on the heat extracted from underground coal fires according to any one of claims 1 to 6, wherein the pump (10) is a pump capable of adjusting flow rate.

9. Thermal electricity conversion based on the heat extracted from underground coal fires according to any one of claims 1 to 6, wherein pipelines in the cooling water radiator (9) have a multi-loop bending design.

10. Thermal electricity conversion based on the heat extracted from underground coal fires according to any one of claims 1 to 6, wherein the thermoelectric power generation chip sets (6) are covered on a surface of the heat conduction container (4) and formed by connecting in series and in parallel.
